(19) United States
(12) Patent Application Publication
(10) Pub. No.: US 2023/0132812 A1
(43) Pub. Date: May 4, 2023

(54) LASER PROCESSING APPARATUS AND LASER PROCESSING METHOD USING THE SAME

(71) Applicant: Samsung Display Co.,Ltd, Yongin-si (KR)

(72) Inventor: KYUWON SHIM, Hwaseong-si (KR)

(21) Appl. No.: 17/879,912

(22) Filed: Aug. 3, 2022

(30) Foreign Application Priority Data
Oct. 29, 2021 (KR) 10-2021-0147167

(51) Int. Cl. B23K 26/06; H01L 51/56; B23K 26/70; B23K 26/082; B23K 26/12

(52) U.S. Cl. CPC B23K 26/0626; H01L 51/56; B23K 26/705; B23K 26/082; B23K 26/0604; B23K 26/1224

(57) ABSTRACT

A laser processing apparatus includes: a laser light source configured to generate a laser beam; a plurality of scanners, wherein each of the plurality of scanners is configured to move the laser beam along a processing path so that the laser beam is irradiated onto a corresponding workpiece of a plurality of workpieces, respectively; a plurality of lenses respectively disposed between the plurality of scanners and the plurality of workpieces; and a measuring circuit spaced apart from the plurality of lenses with the plurality of workpieces interposed therebetween, wherein: the measuring circuit moves along a measuring path and measures a characteristic of the laser beam; and the measuring path overlaps the processing path of each of the plurality of scanners.

### CROSS-REFERENCE TO RELATED APPLICATION

This U.S. non-provisional patent application claims priority under 35 U.S.C. § 119 of Korean Patent Application No, 10-2021-0147167, filed on Oct. 29, 2021, the disclosure of which is incorporated by reference herein in its entirety.

### TECHNICAL FIELD

The present inventive concept relates to a laser processing apparatus and a laser processing method using the same, and more particularly to, a laser apparatus including a controller and a laser processing method using the laser apparatus.

### DISCUSSION OF THE RELATED ART

Generally, in manufacturing a display device, a laser processing apparatus may be used to cut a substrate or form a hole. For example, by using an optical system, the laser processing apparatus may irradiate a target object with a laser beam that is emitted from a laser light source, and by irradiating a workpiece with a laser beam, processing operations such as marking, exposure, etching, punching, scribing, and dicing may be performed. However, since the output of the laser beam emitted from the laser light source is not uniform, processing quality may be impacted.

### SUMMARY

According to an embodiment of the present inventive concept, a laser processing apparatus includes: a laser light source configured to generate a laser beam; a plurality of scanners, wherein each of the plurality of scanners is configured to move the laser beam along a processing path so that the laser beam is irradiated onto a corresponding workpiece of a plurality of workpieces, respectively, a plurality of lenses respectively disposed between the plurality of scanners and the plurality of workpieces and a measuring circuit spaced apart from the plurality of lenses with the plurality of workpieces interposed therebetween, wherein: the measuring circuit moves along a measuring path and measures a characteristic of the laser beam; and the measuring path overlaps the processing path of each of the plurality of scanners.

In an embodiment of the present inventive concept, the laser processing apparatus further includes a protective window disposed between the plurality of workpieces and the plurality of scanners.

In an embodiment of the present inventive concept, the laser beam passes through the protective window.

In an embodiment of the present inventive concept, the laser processing apparatus further includes a chamber configured to accommodate the plurality of workpieces and the protective window in a vacuum.

In an embodiment of the present inventive concept, the laser processing apparatus further includes a controller configured to calculate measurement data based on the characteristic of the laser beam, to calculate compensation data based on the measurement data, and control an output of the laser beam based on the compensation data.

In an embodiment of the present inventive concept, the compensation data includes a compensation value of each of the plurality of scanners.

In an embodiment of, the present it concept, the controller turns on or oft the laser beam of the laser light source based on a position of the measuring circuit,

In an embodiment of the present inventive concept, the controller controls the measuring path and the processing path of each of the plurality of scanners.

In an embodiment of the present inventive concept, the controller synchronizes a position of the laser beam transmitted by one of the plurality of scanners with a position of the measuring circuit.

In an embodiment of the present inventive concept, the measuring circuit moves in a first direction and a second direction crossing the first direction and measures an optical power of the laser beam.

In an embodiment of the present inventive concept, wherein the plurality of scanners include a first scanner and a second scanner spaced apart from the first scanner, and the plurality of lenses include a first lens and a second lens, wherein the first lens faces the first scanner, and the second lens faces the second scanner.

In an embodiment of the present inventive concept, the measuring path overlaps the first scanner and the second scanner.

According to an embodiment of the present inventive concept, a laser processing method includes: moving a measuring circuit; measuring, with the measuring circuit, a characteristic of a first laser beam provided from a first scanner; measuring, with the measuring circuit, a characteristic of a second laser beam provided from a second scanner spaced apart from the first scanner; calculating measurement data based on the characteristic of each of the first laser beam and the second laser beam; calculating compensation data based on the measurement data; and processing a workpiece based on the compensation data.

In a embodiment of the present inventive concept, the measuring circuit moves along a measuring path.

In an embodiment of the present inventive concept, the calculating of the compensation data includes compensating for an output of the first laser beam and an output for the second laser beam.

In an embodiment of the present inventive concept, the measuring of the characteristic of the first laser beam includes the measuring circuit and the first scanner overlapping each other.

In an embodiment of the present inventive concept, the measuring of the characteristic of the second laser beam includes the measuring circuit and the second scanner overlapping each other.

In an embodiment of the present inventive concept, the measuring of the characteristic of the first laser beam includes moving the measuring circuit based on the first laser beam.

In an embodiment of the present inventive concept, the measuring of the characteristic of the second laser beam includes moving the measuring circuit based on the second laser beam.

In an embodiment of the present inventive concept, the laser processing method further includes: turning off the first laser beam which is performed between the measuring of the characteristic of the first laser beam and the measuring of the characteristic of the second laser beam; and turning off the second laser beam which is performed between the measuring of the characteristic of the second laser beam and the calculating of the measurement data.

### BRIEF DESCRIPTION OF THE DRAWINGS

The above and other features of the present inventive concept will become more apparent by describing in detail embodiments thereof with reference to the attached drawings, in which:

FIG. 1 illustrates a laser processing apparatus according to an embodiment of the present inventive concept;

FIG. 2 is a flowchart illustrating a laser processing method according to an embodiment of the present inventive concept;

FIG. 3 is a perspective view illustrating, a portion of the laser processing apparatus according to an embodiment of the present inventive concept;

FIG. 4A is a plan view illustrating a laser processing path and the movement of a measuring unit according to an embodiment of the present inventive concept;

FIG. 4B is a plan view illustrating a laser processing path and the movement of the measuring unit according to an embodiment of the present inventive concept;

FIG. 5 illustrates a portion of the laser processing apparatus according to an embodiment of the present inventive concept;

FIG. 6A is a graph showing measurement data in accordance with the processing position of the laser processing apparatus according to an embodiment of the present inventive concept;

FIG. 6B is a graph showing compensation data in accordance with the processing position of the laser processing apparatus according to an embodiment of the present inventive concept;

FIGS. 7A and 7B are plan views of a mother substrate and display panels for manufacturing a display device according to an embodiment of the present inventive concept; and

FIG. 8 is a cross-sectional view of a display panel according to an embodiment of the present inventive concept.

### DETAILED DESCRIPTION OF THE EMBODIMENTS

In this specification, it will be understood that when an element (or region, layer, part, etc.) is referred to as being “on”, “connected to” or “coupled to” another element, the element can be directly on, connected or coupled to the other element, or intervening elements may be present.

Like reference numerals may refer to like elements throughout the specification. In addition in the drawings, the thicknesses, ratios, and dimensions of elements may be exaggerated for clarity. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another element. For example, a first element could be termed a second element, and a second element may also be referred to as a first element in a similar manner without departing from the spirit and scope of the present inventive concept. The terms of a singular form may include plural forms unless otherwise specified. As used herein, the singular forms, “a”, “an” and “the” are intended to include the plural forms as well, unless the context clearly indicates otherwise.

In addition, terms, such as “below”, “lower”, “above”, “upper” and the like, may be used herein to describe one element's relation to another element(s) as illustrated in the figures. It will be understood that the spatially relative terms are intended to encompass different orientations of the device in use or operation in addition to the orientation depicted in the figures. For example, if the device in the figures is turned over, components described as “below” or “beneath” other components or features would then be oriented “above” the other components or features. The above terms are relative concepts and may be described based on the directions indicated in the drawings.

Hereinafter, embodiments of the present inventive concept will be described with reference to the accompanying drawings.

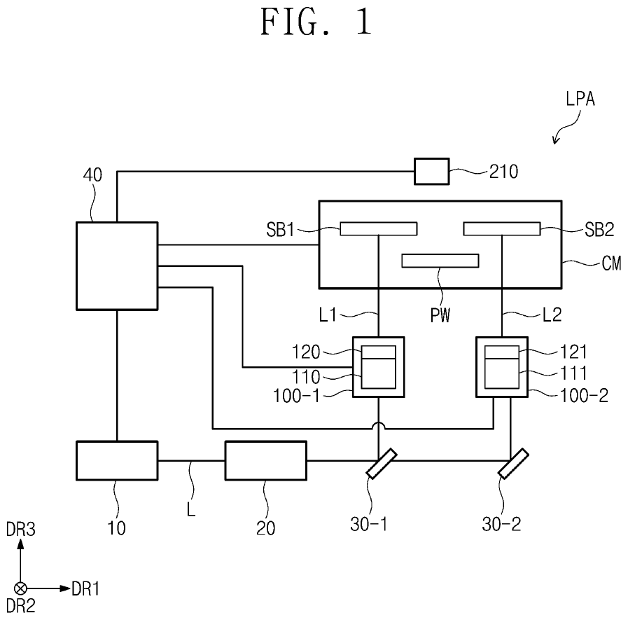

FIG. 1 illustrates a laser processing apparatus according to an embodiment of the present inventive concept.

Referring to FIG. 1, the laser processing apparatus LPA may process a workpiece. The workpiece may include a plurality of substrates SB1 and SB2. The plurality of substrates SB1 and SB2 may include a first substrate SB1 and a second substrate SB2. Each of the plurality of substrates SB1 and SB2 may include a surface, which is parallel to a surface defined by a first direction DR1 and a second direction DR2 crossing the first direction DR1, and have a thickness extending in a third direction DR3 crossing the first direction DR1 and the second direction DR2. In addition, in this specification, a surface defined by the first direction DR1 and the second direction DR2 may be a plane, and “being viewed on a plane” may be defined as being viewed from the third direction DR3.

The laser processing apparatus LPA may perform processing operations such as marking, exposure, etching, punching, scribing, and dicing on the substrates SB1 and SB2.

The laser processing apparatus EPA may include a laser light source 10, a beam delivery system 20, a plurality of reflection mirrors 30-1 and 30-2, a control unit 40, a plurality of laser leads 100-1 and 100-2, a chamber CM, and a measuring unit 210.

The laser light source 10 may generate a laser beam L. The laser light source 10 may provide the laser beam L to the beam delivery system 20. For example, the cross section of the laser beam L generated by the laser light source 10 may have a spot shape.

The beam delivery system 20 may be disposed between the plurality of laser heads 100-1 and 100-2 and the laser light source 10. The beam delivery system 20 may deliver the laser beam L to the plurality of reflection mirrors 30-1 and 30-2. The beam delivery system 20 may be composed of a plurality of lenses and/or mirrors or may be composed of an optical cable.

The laser light source 10 and the beam delivery system 20 according to an embodiment of the present inventive concept may be provided in plurality, and the plurality of laser light sources and the plurality of beam delivery systems may be disposed to correspond respectively to the plurality of laser heads 100-1 and 100-2.

The plurality of reflection mirrors 30-1 and 30-2 may change the optical path of the laser beam L. The plurality of reflection mirrors 30-1 and 30-2 may include a first reflection mirror 30-1 and a second reflection mirror 30-2. The first reflection mirror 30-1 may modify the path of the laser beam L to provide a first laser beam L1. The second reflection mirror 30-2 may modify the path of the laser beam L to provide a second laser beam L2.

The plurality of laser heads 100-1 and 100-2 may respectively irradiate the plurality of substrates SB1 and SB2 with the laser beam L generated from the laser light source 10. The plurality of laser heads 100-1 and 100-2 may include a first laser head 100-1 and a second laser head 100-2. Although, FIG. 1 illustrates, as an example, two laser heads 100-1 and 100-2, the number of laser heads 100-1 and 100-2 according to an embodiment of the present inventive concept is not limited thereto. For example, the number of the plurality of laser heads 100-1 and 100-2 to be provided may be the same as the number of workpieces to be processed by the laser processing apparatus LPA.

The first laser head 100-1 may be spaced apart from the beam delivery system 20 with the first reflection mirror 30-1 interposed therebetween. The first laser head 100-1 may include a first scanner unit 110 and a first lens 120.

The first scanner unit 110 (e.g., a first scanner) may move the irradiation position of the first laser beam L1 to be irradiated onto the first substrate SB1 The first scanner unit 110 may move the first laser beam L1 along a laser processing path. For example, the first scanner unit 110 may include a galvano system or a galvanometer optical scanner. By using the galvano system, the first scanner unit 110 may perform a control operation in which the irradiation point of the first laser beam L1 on the first substrate SB1 is finely moved along the first direction DR1 and the second direction DR2.

The first lens 120 may be disposed between the first scanner unit 110 and the first substrate SB1. The focal distance of the first lens 120 may be adjusted when the first laser beam L1 is irradiated onto the first substrate SB1.

While the first scanner unit 110 moves the irradiation position of the first laser beam L1 along the first processing path, the first lens 120 may remain fixed. However, the present inventive concept is not limited thereto. For example, the first lens 120 may be moved based on the movement of the first scanner unit 110.

The second laser bead 100-2 may be spaced apart from the beam delivery system 20 with the second reflection mirror 30-2 interposed therebetween. The second laser head 100-2 may include a second scanner unit 111 and a second lens 121.

The second scanner unit 111 may move the irradiation position of the second laser beam L2 to be irradiated onto the second substrate SB2. The second scanner unit 111 may move the second laser beam L2 along a laser processing path. For example, the second scanner unit 111 may include a galvano system. By using the galvano system, the second scanner unit 111 may perform a control operation in which the irradiation point of the second laser beam L2 on the second substrate SB2 is finely moved on along the first direction DR1 and the second direction DR2.

The second lens 121 may be disposed between the second scanner unit 111 and the second substrate SB2. The focal distance of the second lens 121 may be adjusted when the second laser beam L2 is irradiated onto the second substrate SB2.

While the second scanner unit 111 moves the irradiation position of the second laser beam L2 along a second processing path, the second lens 121 may remain fixed. However, the present inventive concept is not limited thereto. For example, the first lens 120 may be moved based on the movement of the first scanner unit 110.

The chamber CM may accommodate the first substrate SB1, the second substrate SB2, and a protective window PW. The inside of the chamber CM may be in a vacuum state.

The plurality of substrates SB1 and SB2 may be objects to be processed. Each of the plurality of substrates SB1 and SB2 may move in the first direction DR1 and the second direction DR2 in the chamber CM. The plurality of substrates SB1 and SB2 may include a first substrate SB1 and a second substrate SB2. FIG. 1 illustrates, as an example, two substrates SB1 and SB2, but the number of the plurality of substrates SB1 and SB2 disposed in the chamber CM according to the embodiment of the present inventive concept is not limited thereto.

The first substrate SB1 may overlap the first laser head 100-1. For example, the first substrate SB1 may be disposed above the first laser head 100-1. The first substrate SB1 may be processed by the first laser beam L1. The second substrate SB2 may overlap the second laser head 100-2. The second substrate SB2 may be disposed above the second laser head 100-2. The second substrate SB2 may be processed by the second laser beam L2.

The protective window PW may be disposed below the plurality of substrates SB1 and SB2. For example, the protective window PW may overlap portions of the plurality of substrates SB1 and SB2. The protective window PW may move in the first direction DR1 and the second direction DR2 in the chamber CM. The laser beams L1 and L2 may pass through the protective window PW. The protective window PW may collect foreign substances formed when each of the plurality of substrates SB1 and SB2 is processed. The characteristics of the laser beams L1 and L2 may be modified due to the foreign substances. For example, the foreign substances may reduce the optical powers of the laser beams L1 and L2. According to an embodiment of the present inventive concept, however, the foreign substances may be easily removed by the protective window PW. Therefore, it is possible to increase reliability in performing a laser processing process. The protective window PW according to an embodiment of the present inventive concept may be omitted.

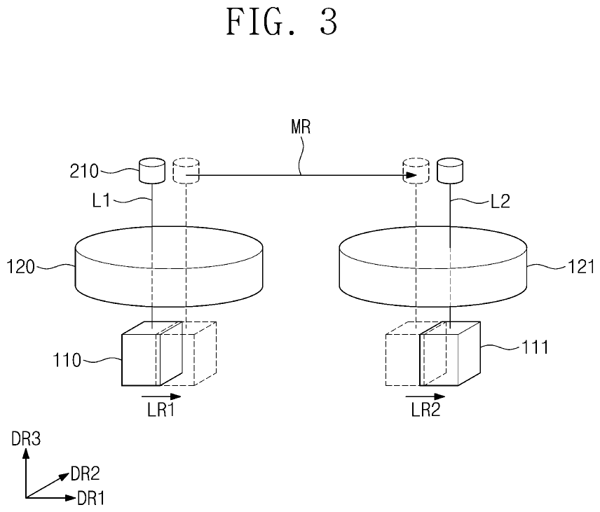

The measuring unit 210 may measure the characteristics and/or properties of the laser beams L1 and L2. The measuring unit 210 may move along a measuring path MR (refer to FIG. 3). The measuring unit 210 may move in the first direction DR1 and the second direction DR2. For example, while each of the plurality of scanner units 110 and 111 moves the laser beams L1 and L2 along, a processing path, the measuring unit 210 may move along the path of the laser beams L1 and L2 to measure the characteristics of the laser beams L1 and L2.

The measuring unit 210 may measure the optical powers of the laser beams L1 and L2. However, this is just an example, and the measuring unit 210 according to an embodiment of the present inventive concept may also measure the profiles of the laser beams L1 and L2. For example, the measuring unit 210 may include a circuit including a receiver, which receives the laser beams L1 and L2, a processor, and a memory.

The control unit 40 (e.g. a control circuit) may control the laser light source 10, the first laser tread 100-1, the second laser head 100-2, the chamber CM, and the measuring unit 210. The control unit 40 may calculate measurement data on the basis of the characteristics of the laser beams L1 and L2. The control unit 40 may calculate compensation data on the basis of the measurement data, The control unit 40 may control the output of the laser beam L on the basis of the compensation data. The control unit 40 may control the measuring path MR (refer to FIG. 3) of the measuring unit 240, a first processing path LR1 of the first scanner unit 110, and a second processing path LR2 of the second scanner unit 111. The operation of the control unit 40 will be described later.

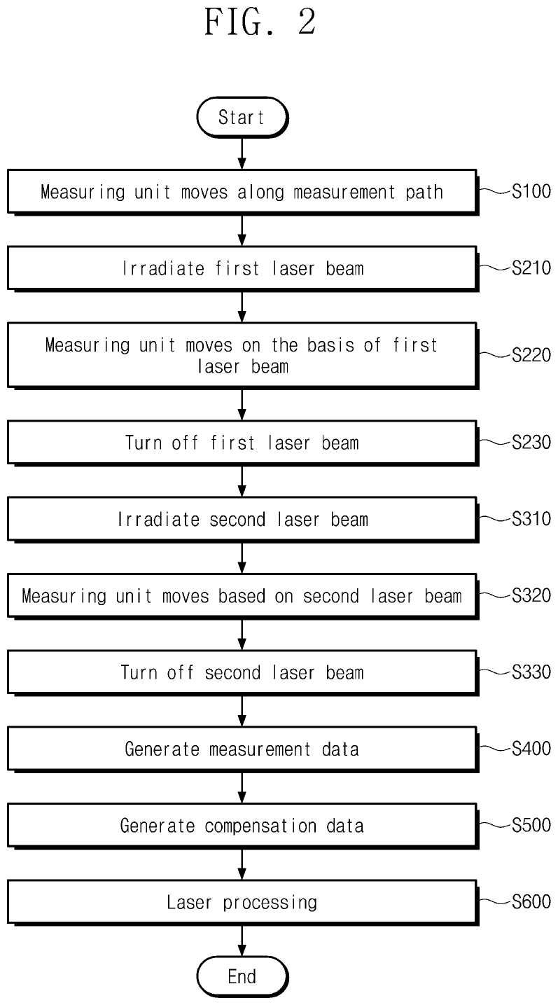

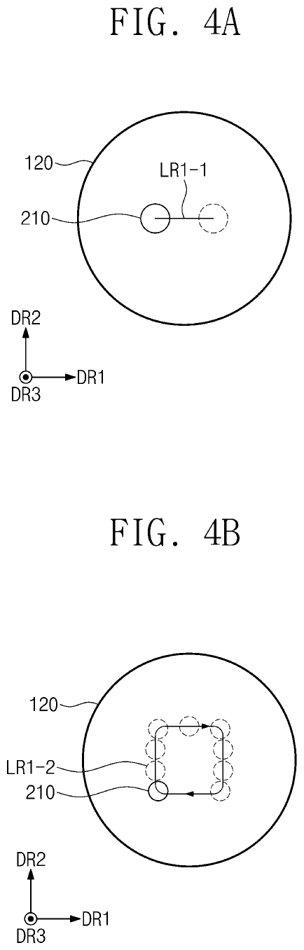

FIG. 2 is a flowchart illustrating a laser processing method according to an embodiment of the present inventive concept. FIG. 3 is a perspective view illustrating a portion of the laser processing apparatus according to an embodiment of the present inventive concept, FIG. 4A is a plan view illustrating a laser processing path and the movement of a measuring unit according to an embodiment of the present inventive concept. FIG. 4B is a plan view illustrating a laser processing path and the movement of the measuring unit according to an embodiment of the present inventive concept.

Referring to FIGS. 1 to 4B, the measuring unit 210 may continuously move along the measuring path MR (S100).

The control unit 40 may turn on the first laser beam L1. The control unit 40 may control the operation of the first laser beam L1 according to the position of the measuring unit 210. For example, when viewed on a plane, the control unit 40 may turn on the first laser beam L1 when the measuring unit 210 overlaps the first scanner unit 110.

The first scanner unit 110 may irradiate the first laser beam L1 along the first processing path LR1 (S210).

The measuring, unit 210 may move on the basis of the first laser beam L1 (S220). When viewed on a plane, the first processing path LR1 may overlap the measuring path MR. The first processing path LR1 may be provided in various shapes.

For example, referring to FIG. 4A, the first scanner unit 110 may move the first laser beam L1 along a first processing path LR1-1. The measuring unit 210 may move along the measuring path MR, which corresponds with the first processing path LR1. The first processing path LR1-1 may extend in a direction parallel to the first direction DR1. In this case, the first processing path LR1-1 nay overlap the measuring path MR of the measuring unit 210.

For example, referring to FIG. 4B, the first scanner unit 110 may move the first laser beam L1 along a first processing path LR1-2. The measuring unit 210 may move along the measuring path MR, which corresponds to the first processing path LR1-2. For example, the measuring unit 210 may move along with the first laser beam L1. The first processing path LR1-2 may have a closed shape, such as a circular shape, a square shape, a square shape with rounded corners, or any other type of polygonal shape. In this case, the first processing path LR1-2 may overlap the measuring path MR of the measuring unit 210.

The measuring unit 210 may measure the characteristic of the first laser beam L1 provided from the first scanner unit 110. The control unit 40 may synchronize the position of the first laser beam L1 irradiated by the first scanner unit 110 with the position of the measuring unit 210.

When viewed on a plane, the measuring unit 210 may overlap the first scanner unit 110.

The control unit 40 may turn off the first laser beam L1 (S230). For example, when viewed on a plane, the control unit 40 may turn off the first laser beam L1 when the measuring unit 210 does not overlap the first scanner unit 110. When the measuring unit 210 finishes measuring the first laser beam L1, the control unit 40 may turn off the first laser beam L1 to continuously measure the output of the second laser beam L2.

The control unit 40 may turn on the second laser beam L2. The control unit 40 may control the operation of the second laser beam L2 according to the position of the measuring unit 210, For example, the control unit 40 may turn on the second laser beam L2 when the measuring unit 210 overlaps the second scanner unit 111 when viewed on a plane.

The second scanner unit 111 may irradiate the second laser beam L2 along the second processing path LR2 (S310).

The measuring unit 210 may move on the basis of the second laser beam L2 (S320), When viewed on plane, the second processing path LR2 may overlap the measuring path MR.

The second processing path LR2 according to an embodiment of the present inventive concept may be the same as the first processing path LR1. However, this is an example, and the second processing path LR2 according to an embodiment of the present inventive concept may be different from the first processing path LR1. In this case, the plurality of substrates SB1 and SB2 may be easily processed by using a processing path for each of the plurality of substrates SB1 and SB2. According to an embodiment of the present inventive concept, the measuring unit 210 may move along the measuring path MR overlapping the first processing path LR1 and the second processing path LR2 to measure the characteristics of the first laser beam L1 and the second laser beam L2 at once. The control unit 40 may calculate the compensation data for each of the plurality of substrates SB1 and SB2. Accordingly, it is possible to provide the laser processing apparatus LPA and the laser processing method with increased processing quality.

The measuring unit 210 may measure the characteristic of the second laser beam L2 provided from the second scanner unit 111. The control unit 40 may synchronize the position of the second laser beam L2 irradiated by the second scanner unit 111 with the position of the measuring unit 210.

When viewed on a plane, the measuring unit 210 may overlap the second scanner unit 111.

The control unit 40 may turn off the second laser beam L2 (S330). For example, the control unit 40 may turn off the second laser beam L2 when the measuring unit 210 does not overlap the second scanner unit 111, when viewed on a plane.

When viewed on a plane, the measuring path MR may overlap the first scanner unit 110 and the second scanner unit 111.

The control unit 40 may generate measurement data on the basis of the characteristic of each of the first laser beam L1 and the second laser beam L2, as collected by the measuring unit 210 (S400).

The control data 40 may generate compensation data on the basis of the measurement data (S500). The control unit 40 may compensate for the output of the laser beam 1, on the basis of the compensation data.

The laser processing apparatus LPA may process the substrates SB1 and SB2 by irradiating the laser beams L1 and L2 onto the substrates SB1 and SB2 along the laser processing path on the basis of the compensation data (S600).

The inside of the chamber CM may be a vacuum. Foreign substances may be formed when the plurality of substrates SB1 and SB2, which are disposed in the chamber CM, are processed. When the foreign substances overlap the paths of the laser beams L1 and L2, the optical powers the laser beams L1 and L2 configured to process file plurality of substrates SB1 and SB2 may be reduced. According to an embodiment of the present inventive concept, the measuring unit 210 may continuously measure the optical power of each of the laser beams L1 and L2 irradiated from the plurality of scanner units 110 and 111, and may calculate compensation data on the basis of the measured optical powers to provide adjusted optical powers of the laser beams L1 and L2 configured to process the substrates SB1 and SB2. Accordingly, it is possible to provide a laser processing apparatus LPA and a laser processing method with increased processing quality.

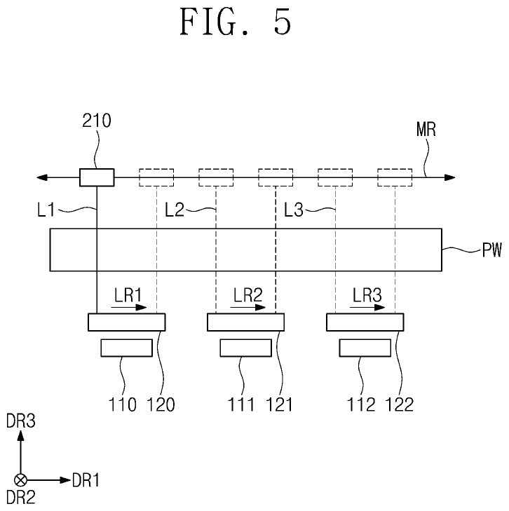

FIG. 5 illustrates a portion of the laser processing apparatus according to art embodiment of the present inventive concept.

Referring to FIG. 5, the measuring unit 210 may move along a measuring path MR.

A first scanner unit 110 may irradiate a first laser beam L1 along a first processing path LR1 The measuring unit 210 may measure the characteristic of the first laser beam L1.

A second scanner unit 111 may irradiate a second laser beam L2 along a second processing path LR2. The measuring unit 210 may measure the characteristic of the second laser beam L2.

A third scanner unit 112 may irradiate a third laser beam L3 along a third processing path LR3. The measuring unit 210 may measure the characteristic of the third laser beam L3.

FIG. 5 illustrates, as an example, three scanner units 110, 111, and 112 and that three processing paths LR1, LR2, and LR3 are measured and compensated for, but the number of scanner units and the number of processing paths to be measured according to an embodiment of the present inventive concept are not limited thereto.

The measuring unit 210 may measure the characteristics of the laser beams L1 , L2, and L3 at once, which are respectively emitted from the plurality of scanner units 110, 111, and 112 that are configured to process objects.

Unlike the present inventive concept, when the characteristic of each of the laser beams L1, L2, and L3 is measured, it may take a first time for the measuring unit to move to a position to measure one laser beam, a second time for the measuring unit to stop to measure the one laser beam, a third time to attain thermal saturation for measuring the optical power of the one laser beam, and a fourth time for the measuring unit to measure the one laser beam. The first time may be about 4 seconds. The second time ma be about 1 second. The third time may be about 15 seconds. The fourth time may be about 5 seconds. For example, the time for measuring one laser beam may be about 25 seconds. For example, it may take about 75 seconds to measure the three laser beams illustrated in FIG. 5. According to an embodiment of the present inventive concept, however, it may take a first measurement time to attain the thermal saturation of the plurality of laser beams L1 , L2, and L3 and a second measurement time for the measuring unit 210 to measure each of the plurality of laser beams L1, L2, and L3. The first measurement may be about 15 seconds. The second measurement time may be about 1 seconds. For example, the time for measuring the plurality of laser beams L1, L2, and L3 may be about 26 seconds. Accordingly, it is possible to provide a laser processing apparatus LPA and a laser processing method with a shortened processing time of a substrate.

In addition, according to an embodiment of the present inventive concept, while the first scanner unit 110 moves the first laser beam L1 along the first processing path LR1, the measuring unit 210 of the laser processing apparatus LPA may move with first laser beam L1 to measure the characteristic of the first laser beam L1 in real time. After measuring the characteristic of the first laser beam L1, the measuring unit 210 may continuously move with the second laser beam L2 to measure the characteristic of the second laser beam L2 in real time while the second scanner unit 111 moves the second laser beam L2 along the second processing path LR2. After measuring the characteristic of the second laser beam L2, the measuring unit 210 may continuously move with the third laser beam L3 to measure the characteristic of the third laser beam L3 in real time while the third scanner unit 112 moves the third laser beam L3 along the third processing path LR3. Accordingly, the measuring unit 210 may compensate for the optical powers of the laser beams L1, L2, and L3 in real time according to the position of each of the plurality of processing paths LR1, LR2, and LR3 to provide a uniform optical power to all of the plurality of processing paths LR1, LR2 and LR3. Accordingly, it is possible to provide a laser processing apparatus LPA and a laser processing method with a shortened processing time and an increase in the substrate processing quality.

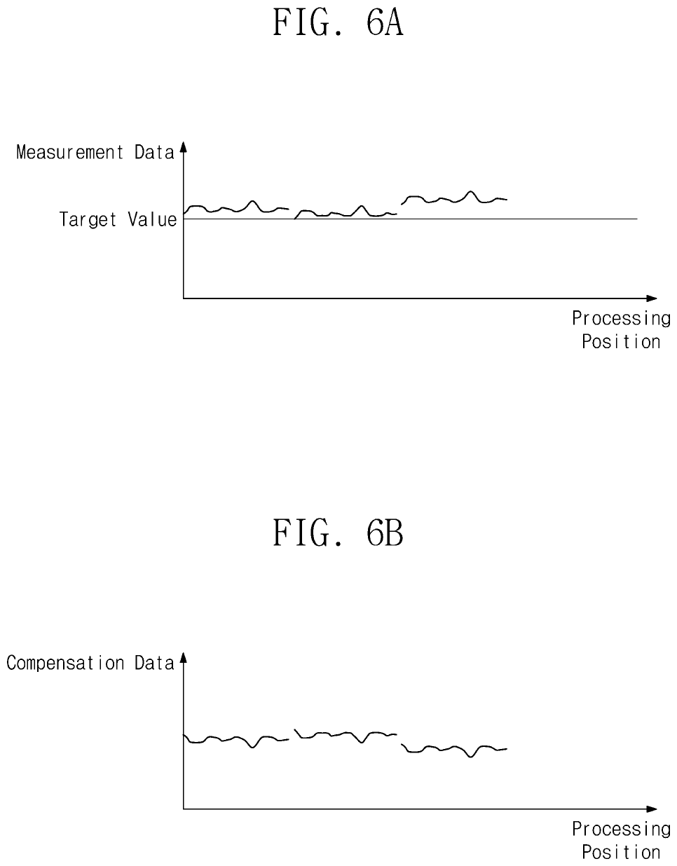

FIG. 6A is a graph showing measurement data in accordance with the processing position of the laser processing apparatus according to an embodiment of the present inventive concept. FIG. 68 is a graph showing compensation data in accordance with the processing position of the laser processing apparatus according to an embodiment of the present inventive concept.

Referring to FIGS. 1, 6A, and 68, the measuring unit. 210 may measure the characteristics of the laser beams L1 and L2. The characteristic of each of the laser beams L1 and L2 may be an optical power of each of the laser beams L1 and L2 The measuring unit 210 may measure an optical power value according to a processing position to generate measurement data. A user may set a target value for the uniform processing of the plurality of substrates SB1 and SB2.

The control unit 40 may calculate compensation data on the basis of the measurement data and the target value. The compensation data may include the compensation value of each of the plurality of scanner units 110 and 111. The compensation data may be generated based on a difference between the measurement data, which corresponds to each point of the laser processing path, and the target value.

The laser processing apparatus LPA may compensate for the optical powers of the laser beams L1 and L2 in real time according to the positions of the processing paths LR1 and LR2, respectively, to provide a uniform optical power to a workpiece in the entire processing paths LR1 and LR2.

On the basis of the compensation data, the laser processing apparatus LPA may emit the laser beams L1 and L2 onto the plurality of substrates SB1 and SB2 along the laser processing path to process the plurality of substrates SB1 and SB2.

According to an embodiment of the present inventive concept, by using the compensation data, the laser processing apparatus LPA may provide an optimal optical power for processing each of the plurality of substrates SB1 and SB2. Accordingly, it is possible to provide a laser processing apparatus LPA and a laser processing method with an increase in the processing quality.

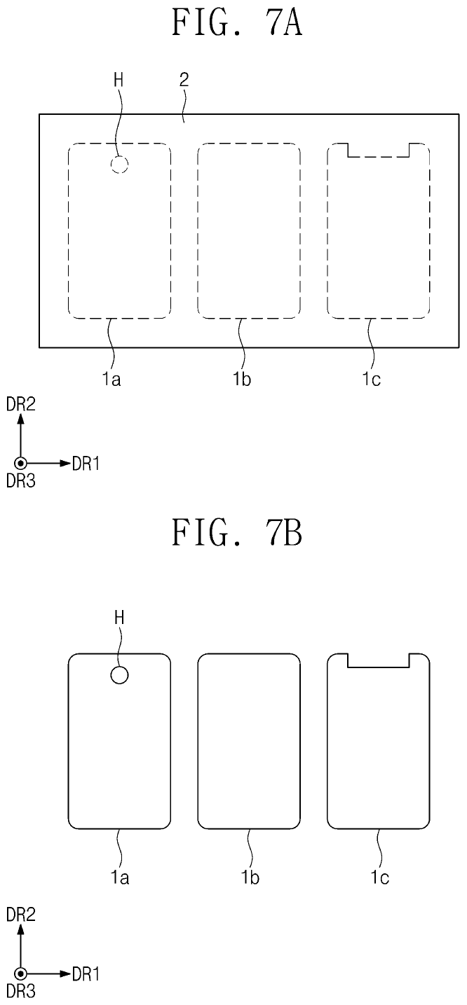

FIGS. 7A and 7B are plan views of a mother substrate and display panels for manufacturing a display device according to an embodiment of the present inventive concept.

Referring to FIGS, 7A and 713, the mother substrate 2 may include a plurality of cells 1a, 1b, and 1c, each of which forms a display panel. The plurality of cells 1a, 1b, and 1c may be referred to as a plurality of display panels 1a, 1b, and 1c. The mother substrate 2 may be cut along a cutting line (dotted line in the drawing). Accordingly, the display panels 1a, 1b, and 1c having various shapes may be separated from the mother substrate 2 after the mother substrate 2 is cut. When cutting the mother substrate 2, the laser processing apparatus LPA (refer to FIG. 1) according to an embodiment of the present inventive concept may be used. For example, when the display panel 1a has a hole H provided therein, the laser processing apparatus LPA (refer to FIG. 1) and the laser processing method may be used for forming the hole H.

According to an embodiment of the present inventive concept, the laser processing apparatus LPA (refer to FIG. 1) may collect the measurement data of the entire mother substrate 2 at once by using the measuring unit 210 (refer to FIG. 1). The control unit 40 (refer to FIG. 1) may calculate compensation data for compensating for the optical power of the laser beam L (refer to FIG. 1) on the basis of the measurement data. The laser processing apparatus LPA (refer to FIG. 1) may process the mother substrate 2 by using the compensated laser beam L (refer to FIG. 1). Accordingly, it is possible to provide the laser processing apparatus LPA (refer to FIG. 1) and the laser processing method with a shortened processing, time and an increase in the substrate processing quality.

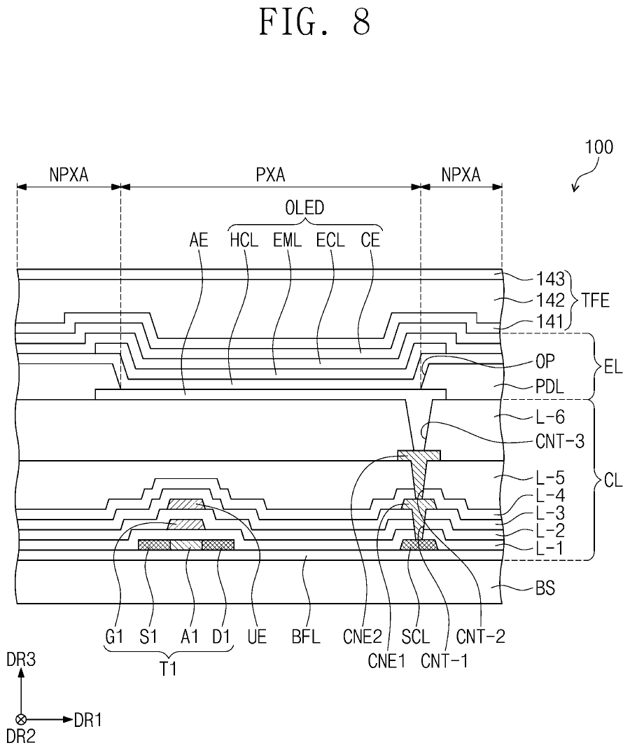

FIG. 8 is a cross-sectional view of a display panel according to an embodiment of the present inventive concept.

Referring to FIG. 8, the display panel 100 may include a base layer BS, a circuit layer CL, a light-emitting element layer EL, and an encapsulation layer TFE. The display panel 100 may include a plurality of insulating layers, a semiconductor pattern, a conductive pattern, a signal line, and the like. An insulating layer, a semiconductor layer, and a conductive layer may be formed by a process such as coating and deposition. Thereafter, the insulating layer, the semiconductor layer, and the conductive layer may be selectively patterned through a photolithography process. In this way, the semiconductor pattern, the conductive pattern, the signal line, and the like included in the circuit layer CL and the light-emitting element layer EL may be formed. The base layer BS may be a base substrate configured to support the circuit layer CL and the light-emitting element layer EL.

The base layer BS may include a synthetic resin layer. The synthetic resin layer may include a thermosetting resin. For example, the base layer BS may have a multi-layered structure. For example, the base layer BS may include a first synthetic resin layer, a silicon oxide layer disposed on the first synthetic resin layer, an amorphous silicon layer disposed on the silicon oxide layer, and a second synthetic resin layer disposed on the amorphous silicon layer. The silicon oxide layer and the amorphous silicon layer may be referred to as a base barrier layer. However, the present inventive concept is not limited thereto. For example, the base layer BS may be a single layered structure.

The circuit layer CL may be disposed on the base layer BS. The circuit layer CL may provide a signal for driving a light-emitting element OLED included in the light-emitting element layer EL. The circuit layer CL may include a buffer layer BFL, a transistor T1, a first insulating layer L-1, a second insulating layer L-2, a third insulating layer L-3, and a fourth insulating layer L-4, a fifth insulating layer L-5, and a sixth insulating layer L-6.

The buffer layer BFL may increase a bonding force between the base layer BS and the semiconductor pattern. The buffer layer BFL may include a silicon oxide layer and a silicon nitride layer. The silicon oxide layer and the silicon nitride layer may be alternately stacked on each other.

The semiconductor pattern may be disposed on the buffer layer BFL. The semiconductor pattern may include polysilicon. However, the embodiment of the present inventive concept is not limited thereto, and the semiconductor pattern may include, for example, amorphous silicon or metal oxide.

FIG. 8 illustrates only a portion of the semiconductor pattern, and on a plane, the semiconductor pattern may be disposed in another region of the display panel 100. The semiconductor pattern may be arranged in a specific rule. The semiconductor pattern may have different electrical properties depending on whether it is doped or not. The semiconductor pattern may include a first region and a second region. The first region has a high conductivity, and the second region has a low conductivity. The first region may be doped with an N-type dopant or a P-type dopant. A P-type transistor may include a doped region doped with a P-type dopant, and an N-type transistor may include a doped region doped with an N-type dopant. The second region may he a non-doped region or a region doped with a lower concentration than the first region.

The conductivity of the first region may be greater than that of the second region, and the first region may act as an electrode or a signal line. The second region may substantially correspond to an active region (or, e.g., a channel) of a transistor. In other words, a first portion of the semiconductor pattern may be an active region of a transistor. A second portion of the semiconductor pattern may be a source region or drain region of the transistor, and a third portion of the transistor may be a connection electrode or a connection signal line.

The display panel 100 may have a plurality of pixels provided therein. For example, each of the plurality of pixels may have a circuit including seven transistors, one capacitor, and a light-emitting element, and the circuit diagram of the pixel may be modified in various forms. FIG. 8 illustrates, as an example, the transistor T1 and the light-emitting element OLED included in each of the plurality of pixels. The transistor T1 may include a source S1, an active A1, a drain D1, and a gate G1.

The source S1, the active A1, and the drain D1 of the transistor T1 may be formed from a semiconductor pattern. The source S1 and the drain D1 may be separated from each other by the active A1, in a cross sectional view. FIG. 5 illustrates a portion of the laser processing apparatus.

The first insulating layer L-1 may be disposed on the buffer layer BFL. The first insulating layer L-1 may overlap the plurality of pixels in common and cover the semiconductor pattern. The first insulating layer L-1 may be an inorganic layer and/or an organic layer and have a single-layered or multi-layered structure. The first insulating layer L-1 may include at least one of aluminum oxide, titanium oxide, silicon oxide, silicon oxynitride, silicon nitride, zirconium oxide, and/or hafnium oxide. In this embodiment, the first insulating layer L-1 may be a silicon oxide layer having a single-layered structure. The insulating layers of the circuit layer CL to be described later, as well as the first insulating layer L-1, may he an inorganic layer and/or an organic layer and have a single-layered or multi-layered structure. The inorganic layer may include at least one of the above-described materials.

The gate G1 may be disposed on the first insulating layer L-1. The gate G1 may be a portion of a metal pattern. The gate G1 may overlap the active A1. In the process of doping the semiconductor pattern, the gate G1 may be the same as a mask.

The second insulating layer L-2 may be disposed on the first insulating layer L-1. The second insulating layer L-2 may cover the gate G1. The second insulating layer L-2 may overlap a plurality of pixels in common. The second insulating layer L-2 may be an inorganic layer and/or an organic layer and have a single-layered or multi-layered structure.

An upper electrode UE may be disposed on the second insulating layer L-2. The upper electrode UE may overlap the gate G2. The upper electrode UE may be a portion of a metal pattern. A portion of the gate G2 and the upper electrode UE overlapping the portion of the gate G2 may form a capacitor. However, this is an example, and the upper electrode UE according to an embodiment of the present inventive concept may be omitted.

The third insulating layer L-3 may be disposed on the second insulating layer L-2. The third insulating layer L-3 may cover the upper electrode UE. For example, the third insulating layer L-3 may be an inorganic layer and/or an organic layer and have a single-layered or multi-layered structure. A first connection electrode CNE1 may be disposed on the third insulating layer L-3. The first connection electrode CNE1 may be connected to the connection signal line SCL through a contact hole CNT-1 passing through the first to third insulating layers L-1, L-2, and L-3.

The fourth insulating layer L-4 may be disposed on the third insulating layer L-3. The fourth insulating layer L-4 may cover the first connection electrode CNE1. For example, the fourth insulating layer L-4 may be are inorganic layer and/or an organic layer and have a single-layered or multi-layered structure.

The fifth insulating layer L-5 may be disposed on the fourth insulating layer L-4. For example, the fifth insulating layer L-5 may he an organic layer. A second connection electrode CNE2 may be disposed on the fifth insulating layer L-5. The second connection electrode CNE2 may be connected to the first connection electrode CNE1 through a contact hole CNT-2 passing through the fourth insulating layer L-4 and the fifth insulating layer L-5.

The sixth insulating layer L-6 may be disposed on the fifth insulating layer L-5. The sixth insulating layer L-6 may cover the second connection electrode CNE2. For example, the sixth insulating layer L-6 may be an organic layer.

The light-emitting element layer EL may include a first electrode AE, a pixel defining film PDL, and a light-emitting element OLED.

The first electrode AE may he disposed on the sixth insulating layer L-6. The first electrode AE may be connected to the second connection electrode CNE2 through a contact hole CNT-3 passing through the sixth insulating layer L-6.

An opening OP may be defined in the pixel defining film PDL. The opening OP of the pixel defining film PDL may expose at least a portion of the first electrode AE.

An active region may include a light-emitting region PXA and a non-light-emitting region NPXA adjacent to the light-emitting region PXA. For example, the non-light-emitting region NPXA may at least partially surround the light-emitting region PXA. In this embodiment, the light-emitting region PXA may correspond to a portion of the first electrode AE exposed by the opening OP.

A hole control layer HCL may be commonly disposed in the light-emitting region PXA and the non-light-emitting region NPXA. The hole control layer HCL may include a hole transport layer and a hole injection layer. A light-emitting layer EML may be disposed on the hole control layer HCL. The light-emitting layer EML may be disposed in a region corresponding to the opening OP. For example the light-emitting layer EML may be separately formed in each of the pixels.

An electron control layer ECL may be disposed on the light-emitting layer EML, The electron control layer ECL may include an electron transport layer and an electron injection layer. The hole control layer HCL and the electron control layer ECL may be commonly formed in the plurality of pixels by using an open mask.

The second electrode CE may be disposed on the electron control layer ECL. For example, the second electrode CE may have an integral shape. The second electrode CE may be commonly disposed in the plurality of pixels. The second electrode CE may be a common electrode CE.

The encapsulation layer TFE may be disposed on the light-emitting element layer EL to cover the light-emitting element layer EL. The encapsulation layer TFE may include a first inorganic encapsulation layer 141, an organic encapsulation layer 142, and a second inorganic encapsulation layer 143, which are sequentially stacked along the third direction DR3. However, this is an example, and the encapsulation layer 140 according to an embodiment of the present inventive concept is not limited thereto. For example, the encapsulation layer 140 according to an embodiment of the present inventive concept may further include a plurality of inorganic layers and a plurality of organic layers.

The first inorganic encapsulation layer 141 may prevent external moisture or oxygen from penetrating into the light-emitting element layer EL. For example, the first inorganic encapsulation layer 141 may include silicon nitride, silicon oxynitride, silicon oxide, or a combination thereof.

The organic encapsulation layer 142 may be disposed on the first inorganic encapsulation layer 141 to provide a flat surface. A curve formed on the upper surface of the first inorganic encapsulation layer 141 or particles existing on the first inorganic encapsulation layer 141 may be covered by the organic encapsulation layer 142. For example, the organic encapsulation layer 142 may include an acryl-based organic layer, but the embodiment of the present inventive concept is not limited thereto.

The second inorganic encapsulation layer 143 may be disposed on the organic encapsulation layer 142 to cover the organic encapsulation layer 142. The second inorganic encapsulation layer 143 may prevent penetration of external moisture or oxygen. The second inorganic encapsulation layer 143 may include silicon nitride, silicon oxynitride, silicon oxide, or a combination thereof.

The display panel 100 may be manufactured by cutting the base layer BS, the circuit layer CL, the light-emitting element layer EL, and the encapsulation layer TFE formed on the mother substrate 2 (refer to FIG. 7A) with the use of the laser processing apparatus LPA (refer to FIG. 1) and the laser processing method according to an embodiment of the present inventive concept.

As described above, the laser processing apparatus may measure the measurement data of all of the plurality of substrates at once by using the measuring unit. The control unit may calculate compensation data for compensating for the optical power of the laser beam on the basis of the measurement data. The laser processing apparatus may process a plurality of substrates by using the compensated laser beam. Accordingly, it is possible to provide the laser processing apparatus and the laser processing method with an increase in the processing quality.

While the present inventive concept has been described with reference to embodiments thereof, it will be understood by those of ordinary skill in the art that various changes in form and details may be made thereto without departing from the spirit and scope of the present invention.

What is claimed is:

1. A laser processing apparatus comprising;
a laser light source configured to generate a laser beam;
a plurality of scanners, wherein each of the plurality of scanners is configured to move the laser beam along a processing path so that the laser beam is irradiated onto a corresponding workpiece of a plurality of workpieces, respectively;
a plurality of lenses respectively disposed between the plurality of scanners and the plurality of workpieces; and
a measuring circuit spaced apart from the plurality of lenses with the plurality of workpieces interposed therebetween,
wherein:
the measuring circuit moves along a measuring path and measures a characteristic of the laser beam; and
the measuring path overlaps the processing path of each of the plurality of scanners.

2. The laser processing apparatus of claim 1, further comprising a protective window disposed between the plurality of workpieces and the plurality of scanners.

3. The laser processing apparatus of claim 2, wherein the laser beam passes through the protective window.

4. The laser processing apparatus of claim 2, further comprising a chamber configured to accommodate the plurality of workpieces and the protective window in a vacuum.

5. The laser processing apparatus of claim 1, further comprising a controller configured to calculate measurement data based on the characteristic of the laser beam, to calculate compensation data based on the measurement data, and control an output of the laser beam based on the compensation data.

6. The laser processing apparatus of claim 5, wherein the compensation data comprises a compensation value of each of the plurality of scanners.

7. The laser processing apparatus of claim 5, wherein the controller turns on or off the laser beam of the laser light source based on a position of the measuring circuit.

8. The laser processing apparatus of claim 5, wherein the controller controls the measuring path and the processing path of each of the plurality of scanners.

9. The laser processing apparatus of claim 5, wherein the controller synchronizes a position of the laser beam transmitted by one of the plurality of scanners with a position of the measuring circuit.

10. The laser processing apparatus of claim 1, wherein the measuring circuit moves in a first direction and a second direction crossing the first direction and measures an optical power of the laser beam.

11. The laser processing apparatus of claim 10, wherein:
the plurality of scanners include a first scanner and a second scanner spaced apart from the first scanner, and
the plurality of lenses include a first lens and a second lens, wherein the first lens faces the first scanner, and the second lens faces the second scanner.

12. The laser processing apparatus of claim 11, wherein the measuring path overlaps the first scanner and the second scanner.

13. A laser processing method comprising:
moving a measuring circuit;
measuring, with the measuring circuit, a characteristic of a first laser beam provided from a first scanner;
measuring, with the measuring circuit, a characteristic of a second laser beam provided from a second scanner spaced apart from the first scanner;
calculating measurement data based on the characteristic of each of the first laser beam and the second laser beam;
calculating compensation data based on the measurement data; and
processing a workpiece based on the compensation data.

14. The laser processing method of claim 13, wherein the measuring circuit moves along a measuring path.

15. The laser processing method of claim 13, wherein the calculating of the compensation data comprises compensating for an output of the first laser beam and an output for the second laser beam.

16. The laser processing method of claim 13, wherein the measuring of the characteristic of the first laser beam comprises the measuring circuit and the first scanner overlapping each other.

17. The laser processing method of claim 16, wherein the measuring, of the characteristic of the second laser beam comprises the measuring circuit and the second scanner overlapping each other.

18. The laser processing, method of claim 13, wherein the measuring of the characteristic of the first laser beam comprises moving the measuring circuit based on the first laser beam.

19. The laser processing method of claim 13, wherein the measuring of the characteristic of the second laser beam comprises moving the measuring circuit based on the second laser beam.

20. The laser processing method of claim 13, further comprising:
turning off the first laser beam which is performed between the measuring of the characteristic of the first laser beam and the measuring of the characteristic of the second laser beam; and
turning off the second laser beam which is performed between the measuring of the characteristic of the second laser beam and the calculating of the measurement data.
